(19) United States
(12) Patent Application Publication
(10) Pub. No.: US 2025/0015773 A1
(43) Pub. Date: Jan. 9, 2025

(54) MULTI-STAGE AMPLIFIER

(71) Applicant: Nippon Telegraph and Telephone Corporation, Tokyo (JP)

(72) Inventor: Tadashi Minotani, Tokyo (JP)

(21) Appl. No.: 18/711,734

(22) PCT Filed: Nov. 22, 2021
(86) PCT No.: PCT/JP2021/042761

§ 371 Date: May 20, 2024

(51) Int. Cl. H03F 3/68

(52) U.S. Cl. CPC H03F 3/68

(57) ABSTRACT

In a multi-stage amplifier, a plurality of amplifier circuits are connected in series, and the amplifier circuit has a 0 dB frequency at which magnitude of a normalized transfer function normalized at a low frequency gain becomes 1 at a frequency other than a direct current.

### CROSS-REFERENCE TO RELATED APPLICATIONS

This application is a national phase entry of PCT Application No. PCT/JP2021/042761, filed on Nov. 22, 2021, which application is hereby incorporated herein by reference.

### TECHNICAL FIELD

The present invention relates to an amplifier that amplifies a baseband signal.

### BACKGROUND

In communication of electrical and optical signals, codes such as Non Return to Zero (NRZ) and 4-Level Pulse Amplitude Modulation (PAM4) which are baseband signals are used (see Non Patent Literature 1). Communication in which these codes are used has an advantage that a configuration of a transmission/reception circuit is simple and delay is low.

Signal processing for signal amplification is performed on a reception side in both cases of the electrical and optical signals. When attenuation of a signal on a communication path is large, signal amplitude becomes small. Therefore, it is necessary to increase a gain of the amplification of the signal. When the gain is increased, amplifier circuits for baseband signals are connected in series in several stages.

However, when the amplifier circuits are connected in an N-stage series, there is a problem that the bandwidth f_N becomes narrower than the 3 dB bandwidth f_{-3 dB} in the case of a single-stage amplifier circuit, and f_N=f_{-3 dB} (2^{1/N}−1)^{0.5} (see Non Patent Literature 2).

### CITATION LIST

### Non Patent Literature

Non Patent Literature 1: Motofumi Kasai, “Kosoku shiriaru denso gijutsu koza (9) kosoku intafesu de shiyo sa reru SerDes—shurui to tokucho, sono rekishi (in Japanese) (SerDes used in High-Speed Serial Transmission Technology Course (9)-Types and Features, Their History)”, EDN Japan, 2018, <https://ednjapan.com/edn/articles/1805/11/news018_4.html>
Non Patent Literature 2: Reza Samadi et al., “Uniform Design of Multi-Peak Bandwidth Enhancement Technique for Multistage Amplifier”, IEEE Transaction on Circuits and Systems, Vol. 54, No. 7, pp. 1489-1499, 2007.

### SUMMARY

### Technical Problem

An object of embodiments of the present invention is to provide a multi-stage amplifier capable of inhibiting a decrease in a band and increasing a gain as compared with a case of a single-stage amplifier circuit.

### Solution to Problem

A multi-stage amplifier according to embodiments of the present invention includes a plurality of amplifier circuits connected in series. The plurality of amplifier circuits have a 0 dB frequency at which magnitude of a normalized transfer function normalized at a low frequency gain becomes 1 at a frequency other than a direct current.

In a configuration example of the multi-stage amplifier of embodiments of the present invention, when a configuration of the amplifier circuit in each stage is expressed with a circuit model, the amplifier circuit may include an input capacitance connected between a signal input terminal and a ground, an amplifier unit configured to amplify a signal input to the signal input terminal, an output resistor of which one end is connected to an output terminal of the amplifier unit, an output capacitance connected between the other end of the output resistor and the ground, and an inductor of which one end is connected to the other end of the output resistor and the other end is connected to a signal output terminal.

In a configuration example of the multi-stage amplifier of embodiments of the present invention, when Rₒ is the output resistor, Cₒ is the output capacitance, L is the inductor, Cₙₓ is the input capacitance of a following-stage circuit connected to the amplifier circuit in each stage, Q=(L/Cₙₓ)^{1/2}/Rₒ, and k_{c}=Cₒ/Cₙₓ, ranges of Q and k_{c} may be expressed by max [(7/32){1−2 (27/28)⁴+(16/7)(k_{c}−0.5)}, ²√{4k_{c}(1−k_{c})}−1]≤(Q−1)≤{0.5−12(k_{c}−0.5)²+12(k_{c}−0.5)³}/8.

In a configuration example of the multi-stage amplifier of embodiments of the present invention, when the 0 dB frequencies of the amplifier circuits in the stages is different, an average of the 0 dB frequencies of the amplifier circuits of the stages may be F1.

In a configuration example of the multi-stage amplifier of embodiments of the present invention, when the resonance sharpness of the amplifier circuits in the stages is different, an average of the resonance sharpness of the amplifier circuits in the stages may be Q.

In a configuration example of the multi-stage amplifier of embodiments of the present invention, when a configuration of the amplifier circuit in each stage is expressed with a circuit model, the amplifier circuit in each stage may include a first amplifier circuit and a second amplifier circuit connected at a stage subsequent to the first amplifier circuit. The first amplifier circuit may include a first input capacitance connected between a signal input terminal and a ground, a first amplifier unit configured to amplify a signal input to the signal input terminal, a first output resistor of which one end is connected to an output terminal of the first amplifier unit, a first output capacitance connected between the other end of the first output resistor and the ground, and a first inductor of which one end is connected to the other end of the first output resistor. The second amplifier circuit may include a second input capacitance connected between the other end of the first inductor and the ground, a second amplifier unit configured to amplify a signal input from the first amplifier circuit, a second output resistor of which one end is connected to an output terminal of the second amplifier unit, a second inductor of which one end is connected to the other end of the second output resistor and the other end is connected to a signal output terminal, and a second output capacitance connected between the signal output terminal and the ground.

In a configuration example of the multi-stage amplifier of embodiments of the present invention, a lower frequency among the 0 dB frequencies of the first amplifier circuits may be equal to the 0 dB frequency of the second amplifier circuit, and a product of an extreme value of the magnitude of the normalized transfer function of the first amplifier circuit at the lower frequency and an extreme value of the magnitude of the normalized transfer function of the second amplifier circuit may be 1.

In a configuration example of the multi-stage amplifier of embodiments of the present invention, when Rₒ is the first output resistor, Cₒ is the first output capacitance, L is the first inductor, Cₙₓ is the second input capacitance, |h(Ωa2)| is an extreme value of a normalized transfer function of the first amplifier circuit at a lower frequency of the 0 dB frequency of the first amplifier circuit, Q=(L/Cₙₓ)^{1/2}/Rₒ, and k_{c}=Cₒ/Cₙₓ, ranges of Q and k may be expressed by |h(Ωa2)|⁻²=(2+3√3)/(3√3)+{4/(3√3)} (k_{c}−1)−({(4+4√3)/9} (Q−1), 1<|h(Ωa2)|⁻²≤1.82,0.5<k_{c}≤1.25.

### Advantageous Effects of Embodiments of the Invention

According to embodiments of the present invention, by connecting in series a plurality of amplifier circuits that have a 0 dB frequency at which the magnitude of a normalized transfer function normalized with a low frequency gain becomes 1 at a frequency other than a direct current, a decrease in the band can be inhibited as compared with the case of a single-stage amplifier circuit, and the gain can be increased as compared with the case of the single-stage amplifier circuit.

### BRIEF DESCRIPTION OF THE DRAWINGS

FIG. 1 is a block diagram illustrating a configuration of a multi-stage amplifier according to a first embodiment of the present invention.

FIG. 2 is a diagram illustrating a circuit model of an amplifier circuit in each stage of the multi-stage amplifier according to the first embodiment of the present invention.

FIG. 3 is a diagram illustrating the circuit model in which a load capacitance is connected to the amplifier circuit in each stage of the multi-stage amplifier according to the first embodiment of the present invention.

FIG. 4 is a diagram illustrating an example of frequency dependence of the normalized transfer function of the amplifier circuit according to the first embodiment of the present invention.

FIG. 5 is a diagram illustrating another example of the frequency dependence of the normalized transfer function of the amplifier circuit according to the first embodiment of the present invention.

FIG. 6 is a diagram illustrating a numerical range in which a ripple of the normalized transfer function is ±3 dB or less in a four-stage multi-stage amplifier.

FIG. 7 is a diagram illustrating another circuit model of the amplifier circuit in each stage of the multi-stage amplifier according to the first embodiment of the present invention.

FIG. 8 is a block diagram illustrating a configuration of a multi-stage amplifier according to a second embodiment of the present invention.

FIG. 9 is a diagram illustrating a circuit model of the amplifier circuit in each stage of the multi-stage amplifier according to the second embodiment of the present invention.

FIG. 10 is a diagram illustrating an example of frequency dependence of a normalized transfer function of the amplifier circuit according to the second embodiment of the present invention.

FIG. 11 is a diagram illustrating an example of frequency dependence of the normalized transfer function of the multi-stage amplifier according to the second embodiment of the present invention.

FIG. 12 is a diagram illustrating another circuit model of the amplifier circuit in each stage of the multi-stage amplifier according to the second embodiment of the present invention.

FIG. 13 is a diagram illustrating another example of frequency dependence of the normalized transfer function of the multi-stage amplifier according to the second embodiment of the present invention.

### DETAILED DESCRIPTION OF ILLUSTRATIVE EMBODIMENTS

### First Embodiment

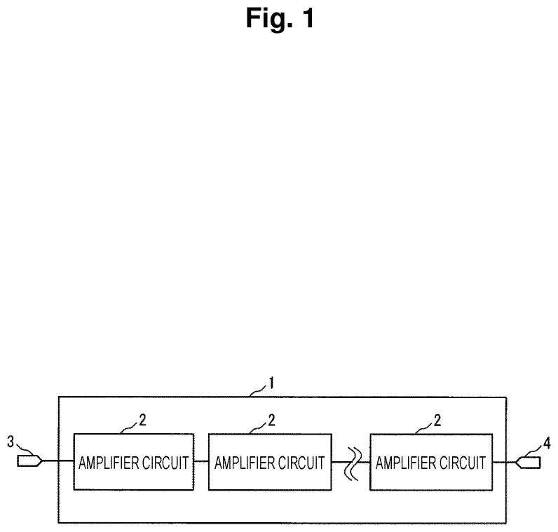

Hereinafter, embodiments of the present invention will be described with reference to the drawings. FIG. 1 is a block diagram illustrating a configuration of a multi-stage amplifier according to a first embodiment of the present invention. In a multi-stage amplifier 1 according to the embodiment, a plurality of amplifier circuits 2 that have a 0 dB frequency at which magnitude of a transfer function normalized at a low frequency gain becomes 1 at a frequency other than a direct current are connected in series between an input terminal 3 and an output terminal 4.

Each amplifier circuit 2 includes a circuit that has an inductor generating resonance, a capacitive input load, and a resistor inhibiting resonance.

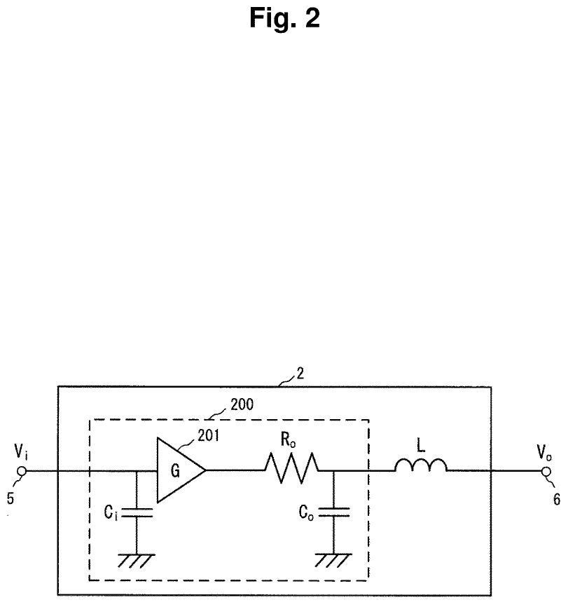

A circuit model of the amplifier circuit 2 is illustrated in FIG. 2. The amplifier circuit 2 includes a main circuit 200 and a resonant inductor L connected between the main circuit 200 and a following-stage input capacitance. Reference numeral 5 in FIG. 2 denotes a signal input terminal of the amplifier circuit 2, and reference numeral 6 denotes a signal output terminal of the amplifier circuit 2.

When the main circuit 200 is modeled, as illustrated in FIG. 2, the main circuit 200 includes an input capacitance Cᵢ connected between a signal input terminal 5 and the ground, an amplifier unit 201 of a gain G that amplifies a signal input to the signal input terminal 5, an output resistor Rₒ of which one end is connected to an output terminal of the amplifier unit 201, and an output capacitance Cₒ connected between the other end of the output resistor Rₒ and the ground.

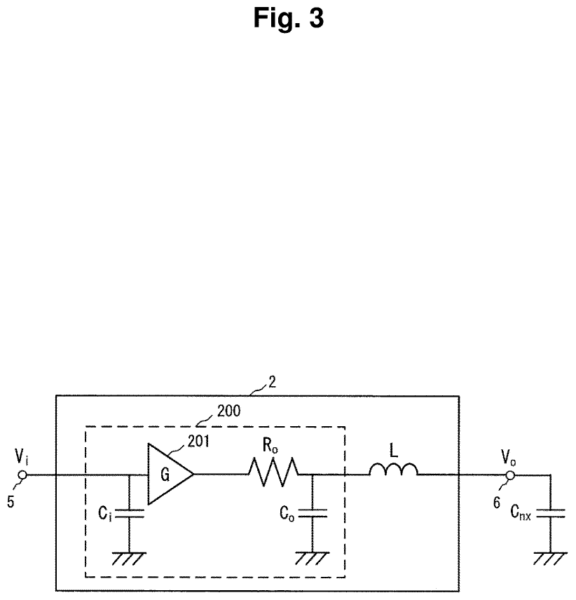

When the amplifier circuit 2 has multiple stages, a load capacitance Cₙₓ (the input capacitance Cᵢ of the following-stage amplifier circuit 2) is connected to the output of the amplifier circuit 2, as illustrated in FIG. 3.

Examples of the main circuit 200 include a CMOS inverter amplifier circuit, an FET source grounding circuit, and a differential amplifier circuit. In the case of a high frequency, an emitter-grounded circuit can also be used as the main circuit 200. The main circuit 200 has a constant low frequency gain G from the vicinity of DC to a cutoff frequency on a high frequency side.

The transfer function of the amplifier circuit 2 is expressed by the following Formula (1).

$$Equation 1$$

$$\frac{{V}_{o}}{{V}_{i}} = \frac{G}{1 - {ω}^{2} {LC}_{nx} + j ω {RoC}_{nx} \{ {C}_{o} ( 1 - {ω}^{2} {LC}_{nx} ) + 1 \}} \qquad ( 1 )$$

In Formula (1), Vᵢ is an input voltage of the amplifier circuit 2, and Vₒ is an output voltage of the amplifier circuit 2. By normalizing Formula (1) with the gain G, a normalized transfer function h(ω) expressed in Formula (2) is obtained.

$$Equation 2$$

$$h ( ω ) = \frac{1}{G} \frac{{V}_{o}}{{V}_{i}} = \frac{1}{1 - {ω}^{2} {LC}_{nx} + j ω {RoC}_{nx} \{ {C}_{o} ( 1 - {ω}^{2} {LC}_{nx} ) + 1 \}} \qquad ( 2 )$$

On the assumption that a normalized angular frequency Ω=ω(LCₙₓ)^{1/2}, a resonance sharpness Q=(L/Cₙₓ)^{1/2}/Rₒ, and the ratio k_{c}=Cₒ/Cₙₓ of the output capacitance Cₒ and the input capacitance Cₙₓ of the following stage, the following Formula (3) is obtained.

$$Equation 3$$

$$h ( Ω ) = \frac{1}{1 - {Ω}^{2} + j \frac{Ω}{Q} \{ {k}_{c} ( 1 - {Ω}^{2} ) + 1 \}} \qquad ( 3 )$$

From Formula (3), a square |h(Ω)|² of the normalized transfer function of the amplifier circuit 2 is expressed by the following Formula (4).

$$Equation 4$$

$${\vert h ( Ω ) \vert}^{2} = \frac{1}{{( 1 - {Ω}^{2} )}^{2} + {( \frac{Ω}{Q} )}^{2} {\{ {k}_{c} ( 1 - {Ω}^{2} ) + 1 \}}^{2}} \qquad ( 4 )$$

The normalized transfer function 0 dB frequency F1=Ω1/2π(F1>0) at which the magnitude of the normalized transfer function of the amplifier circuit 2 is 1, that is, 0 dB can be derived from |h(2πF1)|²=1, and is expressed by the following Formula (5).

$$Equation 5$$

$$2 π F 1 = \sqrt{1 + \frac{2 {k}_{c} - {Q}^{2} \pm Q \sqrt{4 {k}_{c}^{2} - 4 {k}_{c} + {Q}^{2}}}{2 {k}_{c}^{2}}} \qquad ( 5 )$$

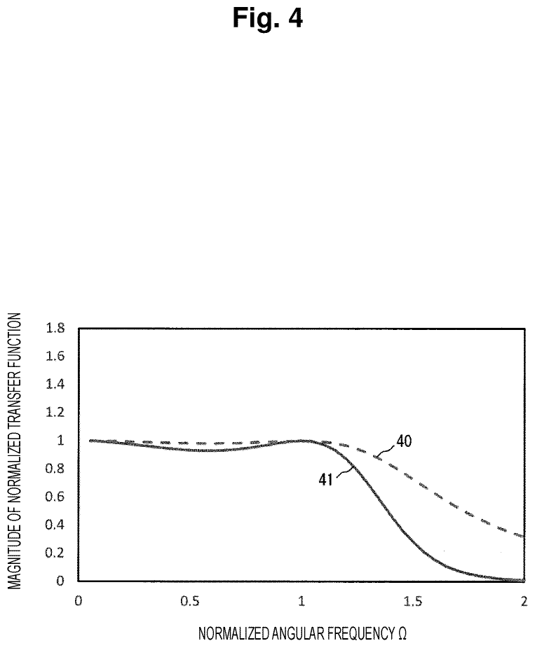

The normalized transfer function 0 dB frequency F1 and the frequency f have a relationship of F1=f(LCₙₓ)^{1/2}. That is, a frequency obtained by normalizing the frequency f with the frequency 1/(LCₙₓ)^{1/2} of resonance generated from the resonant inductor L and the input capacitance Cₙₓ of the following stage is the normalized transfer function 0 dB frequency F1. As an example, in a case of k_{c}=0.5 and Q=1 in which the value of Q is selected to suppress resonance, |h(2πF1)|=1 is obtained at 2πF1=1, and the normalized transfer function of the amplifier circuit 2 is as indicated by a broken line 40 in FIG. 4.

Even when the amplifier circuit 2 is connected in N stages (where N is an integer of 2 or more) as illustrated in FIG. 1, the magnitude of the normalized transfer function of the multi-stage amplifier 1 is |h(2πF1)|^{N}=1 when 2πF1=1. On the other hand, when the amplifier circuit 2 is connected in N stages, the gain of the multi-stage amplifier 1 becomes G^{N}. If G>1, the gain increases by forming the amplifier circuit 2 in multistage.

A normalized transfer function of the multi-stage amplifier 1 when the amplifier circuits 2 are connected in four stages is indicated by a solid line 41 in FIG. 4. Even when the amplifier circuit 2 is connected in four stages, |h(2πF1)|⁴=1 remains at 2πF1=1, and a decrease in the bandwidth up to 2πF1=1 can be inhibited. In the multi-stage amplifier of the related art, the bandwidth when the amplifier circuit that has the bandwidth f0 is connected in four stages is f0(2^{1/4}−1)^{0.5}=0.435 f0, and is reduced by half or more as compared with the bandwidth f0 of the amplifier circuit in one stage. On the other hand, in the multi-stage amplifier 1 according to the embodiment, the decrease in the bandwidth can be inhibited to 20% or less.

When an amplification factor of the amplifier circuit 2 in each stage is set to 1 or more in the multi-stage amplifier 1 according to the embodiment, the decrease in the band can be inhibited and the gain can be increased as compared with the case of the single-stage amplifier circuit. In the multi-stage amplifier 1 according to the embodiment, the gain G of the amplifier circuit 2 in each stage may not be the same.

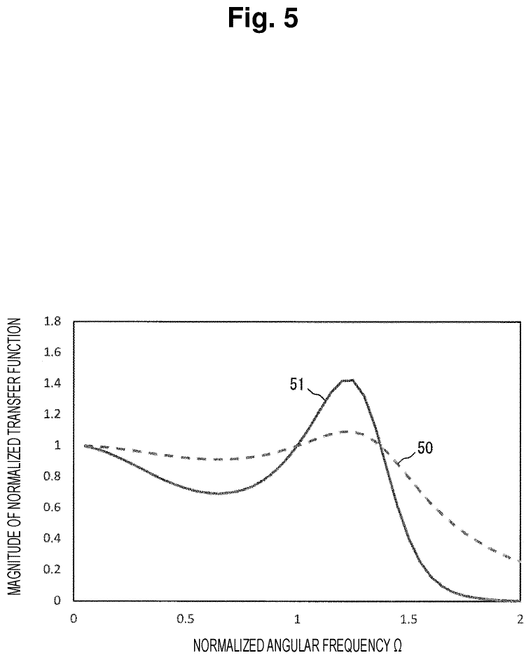

In the above description, k_{c}=0.5 and Q=1 are set as an example, but k_{c}=0.7 and Q=1 may be set. When k_{c}=0.7 and Q=1, the normalized transfer function of the amplifier circuit 2 is expressed as indicated by a broken line 50 in FIG. 5. In the case of k_{c}=0.7, not only |h(2πF1)|=1 is obtained in 2πF1=1, but also there is a frequency of |h(2πF1)|=1 in 2πF1>1, which is a broadband as compared with the case of k_{c}=0.5.

The magnitude of the normalized transfer function of the multi-stage amplifier 1 in which the amplifier circuits 2 are connected in four stages in the case of k_{c}=0.7 and Q=1 is indicated by a solid line 51 in FIG. 5. In the case of k_{c}=0.7 and Q=1, a ripple (a ratio between a maximum value and a minimum value) of the normalized transfer function is greater than the characteristic (solid line 41 in FIG. 4) of the multi-stage amplifier 1 in which the amplifier circuits 2 are connected in four stages in the case of k_{c}=0.5 and Q=1. When the ripple of the normalized transfer function is large, distortion occurs in the signal waveform. Therefore, the ripple is preferably small.

k_{c} and Q for making the ripple of the normalized transfer function ±3 dB or less are obtained. In order to simplify the analysis, (Ωa1)² and (Ωa2)² which are extreme values of the reciprocal of Formula (4) are obtained and expressed by the following Formulae (6) and (7).

$$Equation 6$$

$${( Ω a 1 )}^{2} = \frac{2 {k}_{c}^{2} + 2 {k}_{c} - {Q}^{2} + \sqrt{{Q}^{4} + ( 2 {k}_{c}^{2} - 4 {k}_{c} ) {Q}^{2} + {k}_{c}^{4} + 2 {k}_{c}^{3} + {k}_{c}^{2}}}{3 {kc}^{2}} \qquad ( 6 )$$

$$Equation 7$$

$${( Ω a 2 )}^{2} = \frac{2 {k}_{c}^{2} + 2 {k}_{c} - {Q}^{2} - \sqrt{{Q}^{4} + ( 2 {k}_{c}^{2} - 4 {k}_{c} ) {Q}^{2} + {k}_{c}^{4} + 2 {k}_{c}^{3} + {k}_{c}^{2}}}{3 {k}_{c}^{2}} \qquad ( 7 )$$

|h(Ωa1)| is a maximum value, and |h(Ωa2)| is a minimum value. When |h(Ωa1)| and |h(Ωa2)| near Q=1 and k_{c}=0.5 are obtained by approximate analysis or numerical analysis, |h(Ωa1)| and |h(Ωa2)| are expressed by the following Formulae (8) and (9).

$$Equation 8$$

$${\vert h ( Ω a 1 ) \vert}^{2} = {\{ 1 - 3 {( {k}_{c} - 0.5 )}^{2} + 3 {( {k}_{c} - 0.5 )}^{3} - 2 ( Q - 1 ) \}}^{- 1} \qquad ( 8 )$$

$$Equation 9$$

$${\vert h ( Ω a 2 ) \vert}^{2} = {\{ \frac{28}{27} [ 1 + \frac{4}{7} ( {k}_{c} - 0.5 ) - \frac{8}{7} ( Q - 1 ) ] \}}^{- 1} \qquad ( 9 )$$

In the case of the multi-stage amplifier 1 in which the amplifier circuits 2 are connected in four stages, for example, the condition that the fourth power of |h(Ωa1)|² is 2 or less and the fourth power of |h(Ωa2)|² is ½ or more may be satisfied. From this condition, the following Formulae (10) and (11) are obtained.

$$Equation 10$$

$${\{ 1 - 3 {( {k}_{c} - 0.5 )}^{2} + 3 {( {k}_{c} - 0.5 )}^{3} - 2 ( Q - 1 ) \}}^{- 4} \leq 2 \\ {\{ 1 - 3 {( {k}_{c} - 0.5 )}^{2} + 3 {( {k}_{c} - 0.5 )}^{3} - 2 ( Q - 1 ) \}}^{4} \geq 0.5 \\ 1 - 12 {( {k}_{c} - 0.5 )}^{2} + 12 {( {k}_{c} - 0.5 )}^{3} - 8 ( Q - 1 ) \geq 0.5 \\ ( Q - 1 ) \leq \frac{0.5 - 12 {( {k}_{c} - 0.5 )}^{2} + 12 {( {k}_{c} - 0.5 )}^{3}}{8} \qquad ( 10 )$$

$$Equation 11$$

$${\{ \frac{28}{27} [ 1 + \frac{4}{7} ( {k}_{c} - 0.5 ) - \frac{8}{7} ( Q - 1 ) ] \}}^{- 4} \geq 1 / 2 \\ {\{ \frac{28}{27} [ 1 + \frac{4}{7} ( {k}_{c} - 0.5 ) - \frac{8}{7} ( Q - 1 ) ] \}}^{4} \leq 2 \\ {( \frac{28}{27} )}^{4} \{ 1 + \frac{4}{7} ( {k}_{c} - 0.5 ) - \frac{8}{7} ( Q - 1 ) \} \leq 2 \\ ( Q - 1 ) \geq \frac{7}{32} \{ 1 - 2 {( \frac{27}{28} )}^{4} + \frac{16}{7} ( {k}_{c} - 0.5 ) \} \qquad ( 11 )$$

The condition that (2πF1)² is a real number which is a condition that there is a frequency at which the magnitude of the normalized transfer function of the amplifier circuit 2 is 0 dB may be a condition that the last term Q√(4k_{c}²−4k_{c}+Q²) of the numerator in Formula (5) is a real number. That is, the following Formula (12) may hold.

$$Equation 12$$

$$4 {k}_{c}^{2} - 4 {k}_{c} + {Q}^{2} \geq 0 \qquad ( 12 )$$

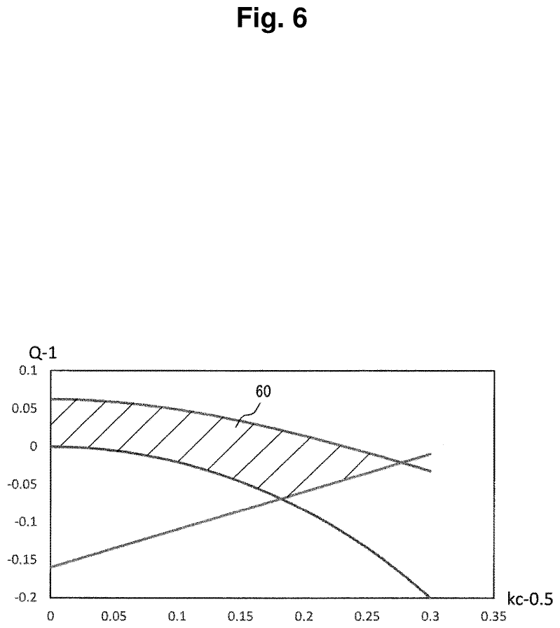

From Formulae (10), (11), and (12), the ranges of Q and k_{c} in which the ripple of the normalized transfer function is ±3 dB or less in the multi-stage amplifier 1 in which the amplifier circuits 2 are connected in four stages are expressed by the following Formula (13). This range is a shaded portion 60 in FIG. 6. In FIG. 6, the vertical axis is Q−1, and the horizontal axis is k_{c}−0.5.

$$Equation 13$$

$$max ( \frac{7}{32} \{ 1 - 2 {( \frac{27}{28} )}^{4} + \frac{16}{7} ( {k}_{c} - 0.5 ) \} , \sqrt[2]{4 {k}_{c} ( 1 - {k}_{c} )} - 1 ) \leq ( Q - 1 ) \leq \frac{0.5 - 12 {( {k}_{c} - 0.5 )}^{2} + 12 {( {k}_{c} - 0.5 )}^{3}}{8} \qquad ( 13 )$$

In the above configuration, in the multi-stage amplifier 1 according to the embodiment, the decrease in the band can be inhibited and the gain can be increased as compared with the case of the single-stage amplifier circuit. As described above, in the multi-stage amplifier 1 according to the embodiment, the gain G of the amplifier circuit 2 in each stage may not be the same.

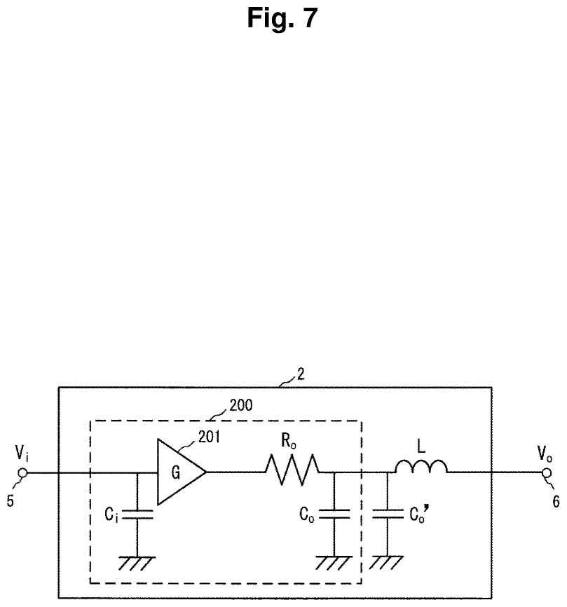

In FIG. 2, k_{c}≥0.5 is satisfied only by the output capacitance Cₒ of the main circuit 200. However, if k_{c}≥0.5 cannot be satisfied only by the unique Cₒ of the main circuit 200, the capacitance Cₒ′ may be additionally connected in parallel with the output capacitance Cₒ as illustrated in FIG. 7. This additional capacitance Cₒ′ may be a wiring capacitance.

In the above description, the normalized transfer function 0 dB frequency at which the magnitude of the normalized transfer function becomes 0 dB is the same in all the stages of the multi-stage amplifier 1.

On the other hand, although the normalized transfer function 0 dB frequency is different in the amplifier circuit 2 in each stage, the 0 dB frequency may be near F1, and the average of the normalized transfer function 0 dB frequency of the amplifier circuit 2 in each stage may be F1. In this case, the frequency is normalized at an average resonance frequency (LCₙₓ)^{-1/2}. The normalized transfer function 0 dB frequency of the amplifier circuit 2 of the k-th stage is expressed as F1+δFₖ, and the magnitude of the normalized transfer function at this time is expressed by the following Formula (14), where the normalized angular frequency Ω1+δₖ=F1+δFₖ in the k-th stage.

$$Equation 14$$

$${\vert {h}_{k} ( Ω 1 + {δΩ}_{k} ) ) \vert}^{2} = \qquad ( 14 )$$

$$\frac{1}{{( 1 - {( Ω 1 + {δΩ}_{k} )}^{2} )}^{2} + {( \frac{Ω 1 + {δΩ}_{k}}{Q} )}^{2} {\{ {k}_{c} ( 1 - {( Ω 1 + {δΩ}_{k} )}^{2} ) + 1 \}}^{2}} = 1$$

From Formula (14), the magnitude of the normalized transfer function at Ω1 in a case where the normalized transfer function 0 dB frequency is Ω1+δₖ is expressed by the following Formula (15) when approximated to the first order term of δΩₖ.

$$Equation 15$$

$$\frac{1}{{( 1 - {( Ω1 )}^{2} )}^{2} + {( \frac{Ω1}{Q} )}^{2} {\{ {k}_{c} ( 1 - {( Ω1 )}^{2} ) + 1 \}}^{2}} - A 1 {δΩ}_{k} = 1 \\ \frac{1}{{( 1 - {( Ω1 )}^{2} )}^{2} + {( \frac{Ω1}{Q} )}^{2} {\{ {k}_{c} ( 1 - {( Ω1 )}^{2} ) + 1 \}}^{2}} = 1 + A 1 {δΩ}_{k} \qquad ( 15 )$$

Here, A1 is a coefficient of a first-order term of δΩₖ, is independent of δΩₖ, and is a value depending on Ω1, Q, and k_{c}. The left side of Formula (15) represents the square |hₖ(Ω1)|² of the magnitude of the normalized transfer function at the normalized angular frequency Ω1. The square |H(Ω1)|² of the magnitude of the normalized transfer function of the entire multi-stage amplifier at the normalized angular frequency Ω1 is expressed by the following Formula (16).

$$Equation 16$$

$${\vert H ( Ω1 ) \vert}^{2} = \prod {\vert {h}_{k} ( Ω1 ) \vert}^{2} = \prod ( 1 + A 1 {δΩ}_{k} ) \qquad ( 16 )$$

In Formula (16), Π is a symbol representing a total power. When Π(1+A1δΩₖ) is approximated by a first-order term of δΩₖ on the right side of Formula (16), the following Formula (17) is obtained.

$$Equation 17$$

$${\vert H ( Ω 1 ) \vert}^{2} = 1 + A 1 \sum {δΩ}_{k} \qquad ( 17 )$$

Since the average of δΩₖ is zero, the magnitude of the normalized transfer function of the multi-stage amplifier 1 at the normalized angular frequency Ω1 is 1. Accordingly, the normalized transfer function 0 dB frequency is different in the amplifier circuit 2 in each stage. However, even when the average of the normalized transfer function 0 dB frequency of the amplifier circuit 2 in each stage is F1, a decrease in the band can be inhibited as compared with the case of the single-stage amplifier circuit, and the gain can be increased.

Furthermore, even when the values of the resonance sharpness are different in the amplifier circuits 2 in the stages, if the average of the resonance sharpness of the amplifier circuits 2 of the stages is Q, the magnitude of the normalized transfer function of the multi-stage amplifier 1 at the normalized angular frequency Ω1 is 1 by the same approximation as described above. Thus, a decrease in the band can be inhibited as compared with the case of the single-stage amplifier circuit, and the gain can be increased.

### Second Embodiment

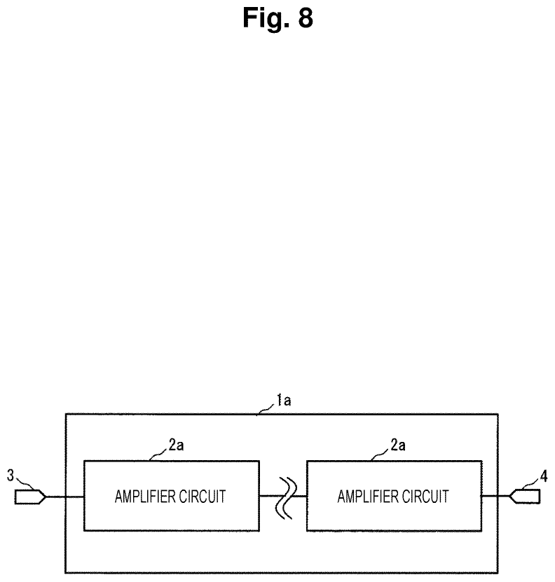

Next, a second embodiment of the present invention will be described. FIG. 8 is a block diagram illustrating a configuration of a multi-stage amplifier according to a second embodiment of the present invention. In a multi-stage amplifier 1a according to the embodiment, a plurality of amplifier circuits 2a that have a 0 dB frequency at which the magnitude of the transfer function normalized by the low frequency gain becomes 1 at frequencies other than a direct current is connected in series between the input terminal 3 and the output terminal 4.

Each amplifier circuit 2a has a configuration in which amplifier circuits that each include an inductor generating resonance, a capacitive input load, and a resistor inhibiting resonance are connected in two stages in series.

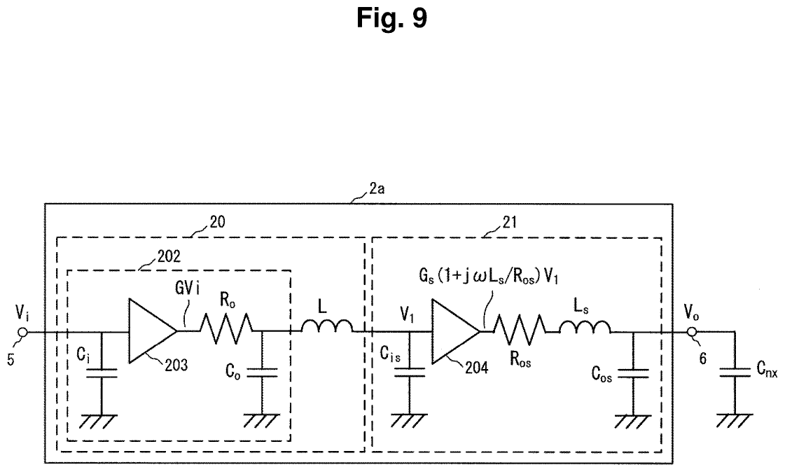

A circuit model of the amplifier circuit 2a is illustrated in FIG. 9. The amplifier circuit 2a includes a first-stage amplifier circuit 20 and a second-stage amplifier circuit 21 connected to a subsequent stage of the amplifier circuit 20.

The first-stage amplifier circuit 20 includes a main circuit 202 and a resonant inductor L connected between the main circuit 202 and the second-stage amplifier circuit 21. When the main circuit 202 is modeled, as illustrated in FIG. 9, the main circuit 202 includes an input capacitance Cᵢ connected between the signal input terminal 5 and the ground, an amplifier unit 203 of a gain G that amplifies a signal input to the signal input terminal 5, an output resistor Rₒ of which one end is connected to the output terminal of the amplifier unit 203, and an output capacitance Cₒ connected between the other end of the output resistor Rₒ and the ground.

Examples of the main circuit 202 include a CMOS inverter amplifier circuit, an FET source ground circuit, and a differential amplifier circuit. In the case of a high frequency, an emitter-grounded circuit can also be used as the main circuit 202. The main circuit 202 has a constant low frequency gain G from the vicinity of DC to a cutoff frequency on a high frequency side.

When the amplifier circuit 21 of the second stage is modeled, the amplifier circuit 21 includes an input capacitance Cᵢₛ connected between the other end of the inductor L and the ground, an amplifier unit 204 of the gain Gₛ (1+jωLₛ/Rₒₛ) that amplifies the signal input from the amplifier circuit 20, an output resistor Rₒₛ of which one end is connected to the output terminal of the amplifier unit 204, an inductor Lₛ of which one end is connected to the other end of the output resistor Rₒₛ and the other end is connected to the signal output terminal 6, and an output capacitance Cₒₛ connected between the signal output terminal 6 and the ground. A load capacitance Cₙₓ (the input capacitance Cᵢ of the following-stage amplifier circuit 2a) is connected to an output of the amplifier circuit 2a. The load capacitance Cₙₓ of the amplifier circuit 20 is the input capacitance Cᵢₛ of the amplifier circuit 21.

As an example of the amplifier circuit 21, there is a CMOS inverter amplifier circuit which has a load resistor Rₒₛ and in which an inductor Lₛ is connected in series to the load resistor Rₒₛ. An FET source-grounded circuit in which the inductor Lₛ is connected in series to the load resistor Rₒₛ and a differential amplifier circuit in which the inductor Lₛ is connected in series to the load resistor Rₒₛ can also be used as the amplifier circuit 21. The amplifier circuit 21 has a constant low frequency gain Gₛ from the vicinity of DC to the cutoff frequency on the high frequency side.

On the assumption that the normalized angular frequency Ω=ω(LCᵢₛ)^{1/2}, the resonance sharpness Q=(L/Cᵢₛ)^{1/2}/Rₒ, and the ratio k_{c}=Cₒ/Cᵢₛ of the output capacitance Cₒ and the input capacitance Cₙₓ of the following stage in the amplifier circuit 20, the square |h(Ω)|² of the normalized transfer function of the amplifier circuit 20 is expressed by Formula (4). The transfer function of the amplifier circuit 21 is expressed by the following Formula (18).

$$Equation 18$$

$$\frac{{V}_{o}}{{V}_{1}} = \frac{{G}_{s} ( 1 + j ω {L}_{s} / {R}_{os} )}{1 - {ω}^{2} {L}_{s} ( {C}_{os} + {C}_{nx} ) + j ω {R}_{os} ( {C}_{os} + {C}_{nx} )} \qquad ( 18 )$$

By normalizing Formula (18) with the gain Gs, the normalized transfer function h2(ω) of the amplifier circuit 21 is obtained.

$$Equation 19$$

$$h 2 ( ω ) = \frac{( 1 + j ω {L}_{s} / {R}_{os} )}{1 - {ω}^{2} {L}_{s} ( {C}_{os} + {C}_{nx} ) + j ω {R}_{os} ( {C}_{os} + {C}_{nx} )} \qquad ( 19 )$$

When a normalized angular frequency Ω=ω(LCᵢₛ)^{1/2}=ω{Lₛ(Cₒₛ+Cₙₓ)/γ}^{1/2}, a resonance sharpness Ω={Lₛ/(Cₒₛ+Cₙₓ)}^{1/2}/Rₒₛ, and γ=Lₛ(Cₒₛ+Cₙₓ)/(LCᵢₛ) in the amplifier circuit 21, the square |h2(Ω)|² of the normalized transfer function of the amplifier circuit 21 is expressed by the following Formula (20).

$$Equation 20$$

$${\vert h 2 ( Ω ) \vert}^{2} = \frac{1 + {γ ( Ω Q 2 )}^{2}}{{( 1 - {γΩ}^{2} )}^{2} + {γ ( \frac{Ω}{Qz} )}^{2}} \qquad ( 20 )$$

The lower frequency F1m of the normalized transfer function 0 dB frequency other than the direct current at which the magnitude of the normalized transfer function of the amplifier circuit 20 is 1 is expressed by the following Formulae (21) from (5).

$$Equation 21$$

$$2 π F 1 m = \sqrt{1 + \frac{2 {k}_{c} - {Q}^{2} - Q \sqrt{4 {k}_{c}^{2} - 4 {k}_{c} + {Q}^{2}}}{2 {k}_{c}^{2}}} \qquad ( 21 )$$

The normalized transfer function 0 dB frequency F2 other than the direct current at which the magnitude of the normalized transfer function of the amplifier circuit 21 is 1 is expressed by the following Formula (22) by solving |h2(Ω)|²=1 from Formula (20).

$$Equation 22$$

$$2 π F 2 = \sqrt{\frac{1}{γ} ( 2 + Q {2}^{2} - \frac{1}{Q {2}^{2}} )} \qquad ( 22 )$$

In the amplifier circuit 2a according to the embodiment, the following Formula (23) holds in order to equalize the normalized transfer function 0 dB frequencies F1m and F2.

$$Equation 23$$

$$\sqrt{\frac{1}{γ} ( 2 + Q {2}^{2} - \frac{1}{Q {2}^{2}} )} = \sqrt{1 + \frac{2 {k}_{c} - {Q}^{2} - Q \sqrt{4 k {c}^{2} - 4 {k}_{c} + {Q}^{2}}}{2 {k}_{c}^{2}}} \frac{1}{γ} ( 2 + Q {2}^{2} - \frac{1}{Q {2}^{2}} ) = 1 + \frac{2 {k}_{c} - {Q}^{2} - Q \sqrt{4 {k}_{c}^{2} - 4 {k}_{c} + {Q}^{2}}}{2 {k}_{c}^{2}} \qquad ( 23 )$$

The right side of Formula (23) can be simplified by Taylor expansion with Q=1, and the following Formula (24) is obtained.

$$Equation 24$$

$$\frac{1}{γ} ( 2 + Q {2}^{2} - \frac{1}{Q {2}^{2}} ) = 1 - \frac{2}{2 {k}_{c} - 1} ( Q - 1 ) Q {2}^{2} = \frac{\begin{matrix}2 - γ \{ 1 - \frac{2}{2 {k}_{c} - 1} ( Q - 1 ) \} + \\ \sqrt{{\{ 2 - γ [ 1 - \frac{2}{2 {k}_{c} - 1} ( Q - 1 ) ] \}}^{2} + 4}\end{matrix}}{2} \qquad ( 24 )$$

In the embodiment, the product of the extreme value of the magnitude |h(Ω)| of the normalized transfer function of the amplifier circuit 20 and the extreme value of the magnitude |h2(Ω)| of the normalized transfer function of the amplifier circuit 21 at a frequency less than F1m is 1. A frequency at which the magnitude |h(Ω)| of the normalized transfer function of the amplifier circuit 20 becomes an extreme value at a frequency less than the frequency F1m is a frequency obtained by dividing Ωa2 of Formula (7) by 2π. The magnitude of the normalized transfer function at this frequency is |h(Ωa2)|.

The frequency Ωb at which the magnitude |h2(Ω)| of the normalized transfer function of the amplifier circuit 21 is an extreme value is obtained by differentiation of Formula (20) and is expressed by Formula (25) below. The magnitude of the normalized transfer function at this frequency is |h2(Ωb)|. The conditional Formula that sets the product of the extreme value of |h(Ω)| and the extreme value of |h2(Ω)| at a frequency less than F1m to 1 is expressed by Formula (26).

$$Equation 25$$

$${( Ω b )}^{2} = \frac{1 - Q 2 \sqrt{Q {2}^{2} + 2}}{2 {γQ2}^{2}} \qquad ( 25 )$$

$$Equation 26$$

$${\vert h ( Ω a 2 ) \vert}^{2} {⌊ h 2 ( Ω b ) ⌋}^{2} = 1 \qquad ( 26 )$$

For example, when Q=1 and k_{c}=1, 2πF1m=1, and |h(Ωa2)|⁻²=(2+3×3^{0.5})/(3×3^{0.5}). When Q2 and γ are obtained by numerical analysis by substituting the values of Q, kc, |h(Ωa2)|⁻² into Formulae (25) and (26), Q2=0.832 and γ=1.247 are obtained.

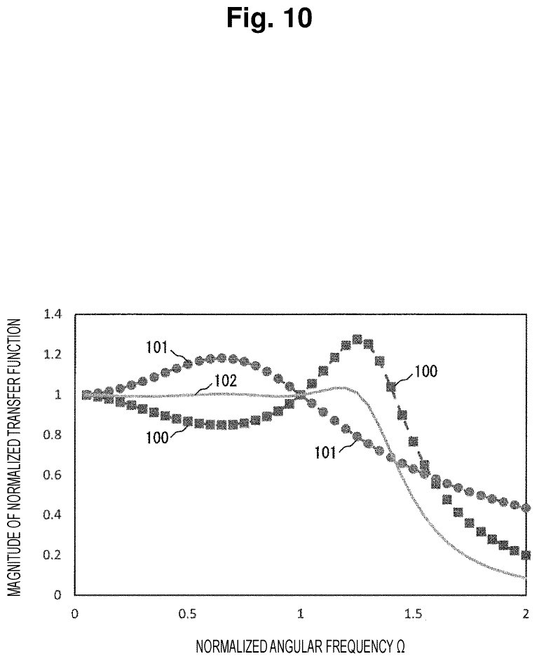

The normalized transfer function of the amplifier circuit 20 in the case of Q=1 and k_{c}=1 is indicated by a broken line 100 in FIG. 10, and the normalized transfer function of the amplifier circuit 21 is indicated by a broken line 101 in FIG. 10. The normalized transfer function of the amplifier circuit 20 and the normalized transfer function of the amplifier circuit 21 intersect at a normalized angular frequency Ω=1 where 2πF1m=1. When the normalized angular frequency Ω=1 or less, it can be understood that the normalized transfer function of the amplifier circuit 20 and the normalized transfer function of the amplifier circuit 21 are symmetric with respect to magnitude 1.

A transfer function obtained by composing the normalized transfer function of the amplifier circuit 20 and the normalized transfer function of the amplifier circuit 21, that is, the normalized transfer function of the amplifier circuit 2a is indicated by a solid line 102 in FIG. 10. It can be understood that a normalized transfer function with a small ripple is obtained by composing the normalized transfer functions.

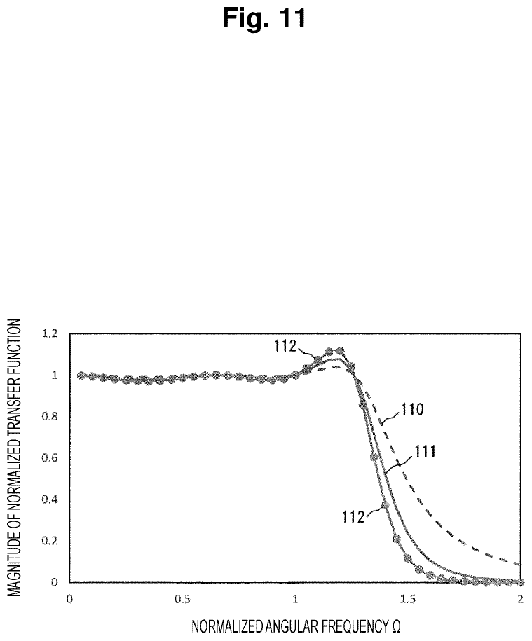

The normalized transfer function of the amplifier circuit 2a is indicated by a broken line 110 in FIG. 11, the normalized transfer function of the multi-stage amplifier 1a in which the amplifier circuit 2a is connected in two stages is indicated by a solid line 111 in FIG. 11, and the normalized transfer function of the multi-stage amplifier 1a in which the amplifier circuit 2a is connected in three stages is indicated by a solid line 112 in FIG. 11.

It can be understood from FIG. 11 that, even when the number of stages of the amplifier circuit 2a increases, the frequency at which the normalized transfer function becomes 1 does not decrease, and a decrease in the bandwidth due to multistage connection of the amplifier circuit 2a can be inhibited. If the amplification factor of the amplifier circuit 2a in each stage is set to 1 or more in the multi-stage amplifier 1a according to the embodiment, a decrease in the band can be inhibited and the gain can be increased as compared with the case of the single-stage amplifier circuit. In the multi-stage amplifier 1a according to the embodiment, the gain of the amplifier circuit 2a in each stage may not be the same. The gain G of the amplifier circuit 20 and the gain Gₛ of the amplifier circuit 21 included in the amplifier circuit 2a in each stage may not be the same.

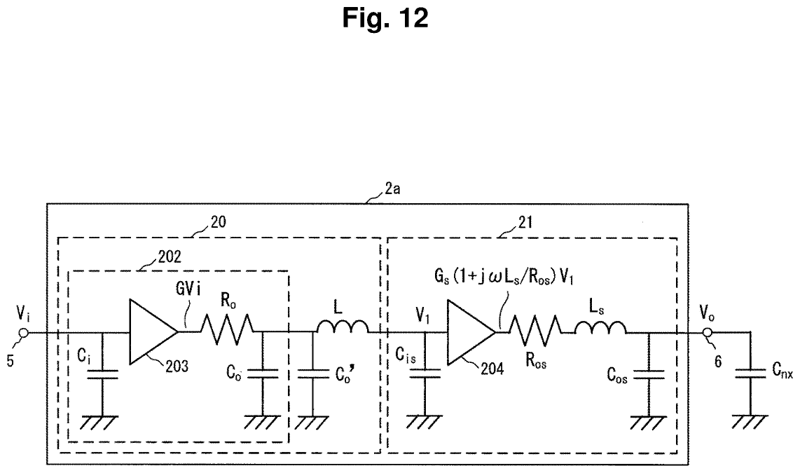

In FIG. 9, k_{c}=1 is set only by the output capacitance Cₒ of the main circuit 202 of the first-stage amplifier circuit 20. However, if k_{c}=1 cannot be set only by the unique Cₒ of the main circuit 202, the capacitance Cₒ′ may be additionally connected in parallel with the output capacitance Cₒ, as illustrated in FIG. 12. This additional capacitance Cₒ′ may be a wiring capacitance.

The following Formula (27) is obtained By Taylor expansion of |h(Ωa2)|⁻² around Q=1 and k_{c}=1.

$$Equation 27$$

$${\vert h ( Ω a 2 ) \vert}^{- 2} = \frac{2 + 3 \sqrt{3}}{3 \sqrt{3}} + \frac{4}{3 \sqrt{3}} ( {k}_{c} - 1 ) - \frac{4 + 4 \sqrt{3}}{9} ( Q - 1 ) \qquad ( 27 )$$

When the conditions of Q and k_{c} under which the ripple of the normalized transfer function of the multi-stage amplifier 1a in which two stages of the amplifier circuits 2a are connected becomes small are obtained by numerical analysis using Formulae (25), (26), and (27), the following Formula (28) is obtained.

$$Equation 28$$

$$1 < {\vert h ( Ω a 2 ) \vert}^{- 2} \leq 1.82 , 0.5 < {k}_{c} \leq 1 \text{.25} \qquad ( 28 )$$

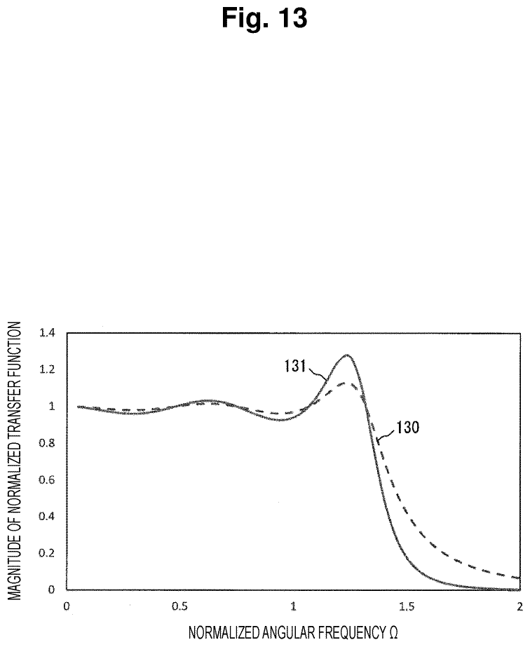

For example, in the case of Q=0.9 and k_{c}=1.2, |h(Ωa2)|-2=1.66, which satisfies the condition of Formula (28). FIG. 13 illustrates the frequency dependence of the normalized transfer function in this case. The normalized transfer function of the amplifier circuit 2a in the case of Q=0.9 and k_{c}=1.2 is indicated by a broken line 130 in FIG. 13. The normalized transfer function of the multi-stage amplifier 1a in which the amplifier circuit 2a is connected in two stages is indicated by a solid line 131 in FIG. 13. It can be understood from FIG. 13 that the ripple of the normalized transfer function of the multi-stage amplifier 1a is inhibited to 3 dB or less.

In FIG. 9, 0.5<k_{c}≤1.25 is set only by the output capacitance Cₒ of the main circuit 202 of the first-stage amplifier circuit 20. However, if 0.5<k_{c}≤1.25 cannot be set only by the unique Cₒ of the main circuit 202, the capacitance Cₒ′ may be additionally connected to be parallel to the output capacitance Cₒ as illustrated in FIG. 12. This additional capacitance Cₒ′ may be a wiring capacitance.

### INDUSTRIAL APPLICABILITY

Embodiments of the present invention can be applied to an amplifier circuit.

### REFERENCE SIGNS LIST

1, 1a MULTI-STAGE AMPLIFIER
2, 2a, 20, 21 Amplifier circuit
5 Signal input terminal
6 Signal output terminal
200, 202 Main circuit
201, 203, 204 Amplifier unit
L, Lₛ Inductor
Cᵢ, Cᵢₛ Input capacitance
Cₒ, Cₒₛ Output capacitance
Rₒ, Rₒₛ Output resistor
Cₙₓ Load capacitance

1-8. (canceled)

9. A multi-stage amplifier, comprising:
a plurality of amplifier circuits connected in series, each of the plurality of amplifier circuits having a 0 dB frequency at which magnitude of a normalized transfer function normalized at a low frequency gain becomes 1 at a frequency other than a direct current.

10. The multi-stage amplifier according to claim 9, wherein when a configuration of each of the plurality of amplifier circuits is expressed with a circuit model, each of the plurality of amplifier circuits includes:
an input capacitance connected between a signal input terminal and ground;
an amplifier configured to amplify a signal input to the signal input terminal;
an output resistor having a first end connected to an output terminal of the amplifier;
an output capacitance connected between a second end of the output resistor and ground; and
an inductor having a first end connected to a second end of the output resistor and having a second end connected to a signal output terminal.

11. The multi-stage amplifier according to claim 10, wherein:
when the output resistor is represented by Rₒ, the output capacitance is represented by Cₒ, the inductor is represented by L, an input capacitance of another one of the plurality of the amplifier circuits in a following stage connected to one of the plurality of amplifier circuits in each stage of the multi-stage amplifier is represented by Cₙₓ, Q=(L/Cₙₓ)^{1/2}/Rₒ, and k_{c}=Cₒ/Cₙₓ, and ranges of Q and k_{c} are expressed by:
$$max ( \frac{7}{32} \{ 1 - 2 {( \frac{27}{28} )}^{4} + \frac{16}{7} ( {k}_{c} - 0.5 ) \} , \sqrt[2]{4 {k}_{c} ( 1 - {k}_{c} )} - 1 ) \leq ( Q - 1 ) \leq \frac{0.5 - 12 {( {k}_{c} - 0.5 )}^{2} + 12 {( {k}_{c} - 0.5 )}^{3}}{8} .$$

12. The multi-stage amplifier according to claim 11, wherein when the 0 dB frequencies of each of the plurality of amplifier circuits is different, an average of the 0 dB frequencies of the plurality of amplifier circuits is F1.

13. The multi-stage amplifier according to claim 11, wherein when a resonance sharpness of each of the plurality of amplifier circuits is different, an average of the resonance sharpness of the plurality of amplifier circuits is Q.

14. The multi-stage amplifier according to claim 9, wherein:
when a configuration of the amplifier circuit in each stage is expressed with a circuit model, the amplifier circuit in each stage includes a first amplifier circuit and a second amplifier circuit connected at a stage subsequent to the first amplifier circuit,
wherein the first amplifier circuit includes:
a first input capacitance connected between a signal input terminal and a ground;
a first amplifier configured to amplify a signal input to the signal input terminal;
a first output resistor having a first end connected to an output terminal of the first amplifier;
a first output capacitance connected between a second end of the first output resistor and ground; and
a first inductor having a first end connected to a second end of the first output resistor, and
wherein the second amplifier circuit includes:
a second input capacitance connected between a second end of the first inductor and ground;
a second amplifier configured to amplify a signal input from the first amplifier circuit;
a second output resistor having a first end connected to an output terminal of the second amplifier;
a second inductor having a first end connected to a second end of the second output resistor and having a second end is connected to a signal output terminal; and
a second output capacitance connected between the signal output terminal and the ground.

15. The multi-stage amplifier according to claim 14, wherein a lower frequency among the 0 dB frequencies of the first amplifier circuit is equal to the 0 dB frequency of the second amplifier circuit, and a product of an extreme value of the magnitude of the normalized transfer function of the first amplifier circuit at the lower frequency and an extreme value of the magnitude of the normalized transfer function of the second amplifier circuit is 1.

16. The multi-stage amplifier according to claim 15, wherein when Rₒ is the first output resistor, Cₒ is the first output capacitance, L is the first inductor, Cₙₓ is the second input capacitance, |h(Ωa2)| is an extreme value of a normalized transfer function of the first amplifier circuit at a lower frequency of the 0 dB frequency of the first amplifier circuit, Q=(L/Cₙₓ)^{1/2}/Rₒ, and k_{c}=Cₒ/Cₙₓ, ranges of Q and k_{c} are expressed by:
$${\vert h ( Ω a 2 ) \vert}^{- 2} = \frac{2 + 3 \sqrt{3}}{3 \sqrt{3}} + \frac{4}{3 \sqrt{3}} ( {k}_{c} - 1 ) - \frac{4 + 4 \sqrt{3}}{9} ( Q - 1 ) 1 < {\vert h ( Ω a 2 ) \vert}^{- 2} \leq 1.82 , 0.5 < {k}_{c} \leq 1 \text{.25} .$$

17. The multi-stage amplifier according to claim 14, wherein when Rₒ is the first output resistor, Cₒ is the first output capacitance, L is the first inductor, Cₙₓ is the second input capacitance, |h(Ωa2)| is an extreme value of a normalized transfer function of the first amplifier circuit at a lower frequency of the 0 dB frequency of the first amplifier circuit, Q=(L/Cₙₓ)^{1/2}/Rₒ, and k_{c}=Cₒ/Cₙₓ, ranges of Q and k_{c} are expressed by:
$${\vert h ( Ω a 2 ) \vert}^{- 2} = \frac{2 + 3 \sqrt{3}}{3 \sqrt{3}} + \frac{4}{3 \sqrt{3}} ( {k}_{c} - 1 ) - \frac{4 + 4 \sqrt{3}}{9} ( Q - 1 ) 1 < {\vert h ( Ω a 2 ) \vert}^{- 2} \leq 1.82 , 0.5 < {k}_{c} \leq 1 \text{.25} .$$

18. A multi-stage amplifier, comprising:
a plurality of amplifier circuits connected in series, each of the plurality of amplifier circuits having a 0 dB frequency at which magnitude of a normalized transfer function normalized at a low frequency gain becomes 1 at a frequency other than a direct current, wherein each of the plurality of amplifier circuits includes:
an amplifier configured to amplify a signal input to a signal input terminal;
an output resistor having a first end connected to an output terminal of the amplifier; and
an inductor having a first end connected to a second end of the output resistor and having a second end connected to a signal output terminal.

19. The multi-stage amplifier according to claim 18, wherein:
when the output resistor is represented by Rₒ, an output capacitance of one of the plurality of amplifier circuits in each of the stages is represented by Cₒ, the inductor is represented by L, an input capacitance of another one of the plurality of the amplifier circuits in a following stage connected to the one of the plurality of amplifier circuits in each stage of the multi-stage amplifier is represented by Cₙₓ, Q=(L/Cₙₓ)^{1/2}/Rₒ, and k_{c}=Cₒ/Cₙₓ, and ranges of Q and k_{c} are expressed by:
$$max ( \frac{7}{32} \{ 1 - 2 {( \frac{27}{28} )}^{4} + \frac{16}{7} ( {k}_{c} - 0.5 ) \} , \sqrt[2]{4 {k}_{c} ( 1 - {k}_{c} )} - 1 ) \leq ( Q - 1 ) \leq \frac{0.5 - 12 {( {k}_{c} - 0.5 )}^{2} + 12 {( {k}_{c} - 0.5 )}^{3}}{8} .$$

20. The multi-stage amplifier according to claim 19, wherein
when a resonance sharpness of each of the plurality of amplifier circuits is different, an average of the resonance sharpness of the plurality of amplifier circuits is Q.

21. A multi-stage amplifier, comprising:
a plurality of amplifier circuits connected in series, each of the plurality of amplifier circuits having a 0 dB frequency at which magnitude of a normalized transfer function normalized at a low frequency gain becomes 1 at a frequency other than a direct current, wherein the amplifier circuit in each stage includes a first amplifier circuit and a second amplifier circuit connected at a stage subsequent to the first amplifier circuit,
wherein the first amplifier circuit includes:
a first amplifier configured to amplify a signal input to a signal input terminal;
a first output resistor having a first end connected to an output terminal of the first amplifier; and a first inductor having a first end connected to a second end of the first output resistor, and
wherein the second amplifier circuit includes:
a second amplifier configured to amplify a signal input from the first amplifier circuit;
a second output resistor having a first end connected to an output terminal of the second amplifier; and
a second inductor having a first end connected to a second end of the second output resistor and having a second end is connected to a signal output terminal.

22. The multi-stage amplifier according to claim 21, wherein a lower frequency among the 0 dB frequencies of the first amplifier circuit is equal to the 0 dB frequency of the second amplifier circuit, and a product of an extreme value of the magnitude of the normalized transfer function of the first amplifier circuit at the lower frequency and an extreme value of the magnitude of the normalized transfer function of the second amplifier circuit is 1.

23. The multi-stage amplifier according to claim 21, wherein when Rₒ is the first output resistor, Cₒ is a first output capacitance of the first amplifier circuit, L is the first inductor, Cₙₓ is a second input capacitance of the second amplifier circuit, |h(Ωa2)| is an extreme value of a normalized transfer function of the first amplifier circuit at a lower frequency of the 0 dB frequency of the first amplifier circuit, Q=(L/Cₙₓ)^{1/2}/Rₒ, and k_{c}=Cₒ/Cₙₓ, ranges of Q and k_{c} are expressed by:
$${\vert h ( Ω a 2 ) \vert}^{- 2} = \frac{2 + 3 \sqrt{3}}{3 \sqrt{3}} + \frac{4}{3 \sqrt{3}} ( {k}_{c} - 1 ) - \frac{4 + 4 \sqrt{3}}{9} ( Q - 1 ) 1 < {\vert h ( Ω a 2 ) \vert}^{- 2} \leq 1.82 , 0.5 < {k}_{c} \leq 1 \text{.25} .$$
